(19) United States
(12) Patent Application Publication
(10) Pub. No.: US 2014/0057385 A1
(43) Pub. Date: Feb. 27, 2014

(54) III-V PHOTOVOLTAIC ELEMENT AND FABRICATION METHOD

(71) Applicants: Stephen W. Bedell, Wappingers Falls, NY (US); Bahman Hekmatshoartabari, White Plains, NY (US); Davood Shahrjerdi, White Plains, NY (US)

(72) Inventors: Stephen W. Bedell, Wappingers Falls, NY (US); Bahman Hekmatshoartabari, White Plains, NY (US); Davood Shahrjerdi, White Plains, NY (US)

(73) Assignee: International Business Machines Corporation, Armonk, NY (US)

(21) Appl. No.: 13/593,138

(22) Filed: Aug. 23, 2012

(51) Int. Cl. H01L 31/0304; H01L 31/0232

(52) U.S. Cl. 438/72; 438/94; 257/E31.02; 257/E31.127

(57) ABSTRACT

A solar cell structure includes stacked layers in reverse order on a germanium substrate. A heterostructure including an (In)GaAs absorbing layer and a disordered emitter layer is provided in the solar cell structures. Controlled spalling may be employed as part of the fabrication process for the solar cell structure, which may be single or multi-junction.

### FIELD

The present disclosure relates to the physical sciences, and, more particularly, to photovoltaic structures comprising III-V absorber material and the fabrication of such structures.

### BACKGROUND

Direct gap III-V materials such as gallium arsenide are attractive candidates for making high efficiency solar cells due to their strong absorption properties. The efficiency of single-junction III-V solar cells can be further improved utilizing emitter/base heterostructures.

In ternary materials, the formation of a CuPt-type superlattice, due to ordered group III and group V sublattices, can reduce the energy bandgap. In contrast, increasing the disordered group III and/or group V sublattices can give rise to an increase in energy bandgap. Growth parameters such as temperature, gas ratio, growth rates and substrate misorientation influence the extent of order/disorder in the sublattices. For example, it is known that increasing Zn doping concentration in InGaP2 as well as growth of InGaP2 on (001) germanium and gallium arsenide substrates with a larger degree of misorientation towards (111) direction tends to increase the extent of disorder in group III sublattices, leading to an increase in bandgap of InGaP2.

Solar cell structures can be initially grown in reverse order to enhance functionality without performance degradation. In other words, the emitter layer may be provided near the bottom of the cell while the BSF layer is at or near the top. A solar cell structure 70 is shown in FIG. 9. The buffer region 74 in the inverted structure 70 is doped with silicon. As indicated in the figure, the buffer layer 74A is formed of Si:In_{0.01}Ga_{0.99}As and is 2.0 μm in thickness while the optional nucleation layer 74B is formed of Si:In_{0.5}Ga_{0.5}P. An etch stop layer 76 is formed between the ohmic contact layer 20 and the buffer layer 74A. A contact layer (not shown) may be provided on the BSF layer 16. The fabrication of a III-V solar cell structure such as shown in FIG. 9 involves growing the layers on a substrate, removing the germanium substrate 22 and the layers between the substrate and ohmic contact layer 20, none of which are part of the active device, and then further processing to produce a finished device. A metal lead (not shown) can then be formed on the contact layer 20.

### SUMMARY

Principles of the present disclosure provide techniques for improving solar cell performance and facilitating manufacture of III-V photovoltaic elements.

An exemplary method provided herein includes obtaining an inverted solar cell structure including a germanium substrate, a base layer comprising gallium arsenide, a back surface field layer adjoining the base layer, a disordered emitter layer between the substrate and the base layer and forming a heterostructure with the base layer, a window layer adjoining the emitter layer, and a contact layer. The method further includes forming a stressor layer on the inverted solar cell structure, attaching a flexible handle layer to the stressor layer, and spalling through the germanium substrate, forming a solar cell structure including the inverted solar cell structure, the stressor layer, the flexible handle layer, and a residual germanium layer.

A second exemplary method includes providing a germanium substrate and growing a single or multi junction solar cell structure including at least one gallium arsenide absorbing layer in inverted order on the germanium substrate, the step of growing the solar cell structure further including growing an emitter layer in the presence of an isoelectric surfactant to cause disordered growth of the emitter layer. The method further includes attaching a stressor layer to the solar cell structure, attaching a flexible handle layer to the metal stressor layer, spalling through the germanium substrate, and removing a residual germanium layer from the solar cell structure.

A photovoltaic structure in accordance with an exemplary embodiment includes an inverted solar cell structure comprising a germanium substrate, a base layer comprising gallium arsenide, a back surface field layer adjoining the base layer, a disordered emitter layer between the substrate and the base layer and forming a heterostructure with the base layer, a window layer adjoining the emitter layer, and a contact layer. A stressor layer is attached to the inverted solar cell structure. A flexible handle layer is attached to the stressor layer, the stressor layer and flexible handle layer being operable to cause a fracture within the germanium substrate.

A second exemplary structure includes an inverted solar cell structure comprising a base layer comprising gallium arsenide, a back surface field layer adjoining the base layer, a disordered emitter layer between the substrate and the base layer and forming a first heterostructure with the base layer, a window layer adjoining the emitter layer, and a contact layer. A stressor layer is attached to the inverted solar cell structure and a flexible handle layer is attached to the stressor layer.

As used herein, “facilitating” an action includes performing the action, making the action easier, helping to carry the action out, or causing the action to be performed. Thus, by way of example and not limitation, instructions executing on one processor might facilitate an action carried out by instructions executing on a remote processor, by sending appropriate data or commands to cause or aid the action to be performed. For the avoidance of doubt, where an actor facilitates an action by other than performing the action, the action is nevertheless performed by some entity or combination of entities.

One or more embodiments of the invention or elements thereof can be implemented in the form of a computer program product including a tangible computer readable recordable storage medium with computer usable program code for performing the method steps indicated. Furthermore, one or more embodiments of the invention or elements thereof can be implemented in the form of a system (or apparatus) including a memory, and at least one processor that is coupled to the memory and operative to perform exemplary method steps. Yet further, in another aspect, one or more embodiments of the invention or elements thereof can be implemented in the form of means for carrying out one or more of the method steps described herein; the means can include (i) hardware module(s), (ii) software module(s), or (iii) a combination of hardware and software modules; any of (i)-(iii) implement the specific techniques set forth herein, and the software modules are stored in a tangible computer-readable recordable storage medium (or multiple such media).

Techniques as disclosed herein can provide substantial beneficial technical effects. For example, one or more embodiments may provide one or more of the following advantages:

High open circuit voltage (V_{oc})

High solar cell efficiency (η)

Increased energy band offset between conduction and valence bands

Simplified fabrication process

These and other features and advantages will become apparent from the following detailed description of illustrative embodiments thereof, which is to be read in connection with the accompanying drawings.

### BRIEF DESCRIPTION OF THE DRAWINGS

FIG. 1 is a schematic illustration of a solar cell structure having a single junction including a disordered emitter layer and wherein certain layers are grown in reverse order;

FIG. 2 is a diagram showing conduction band energy and valence band energy for InGaP grown on germanium;

FIG. 3 is a schematic illustration of a flexible solar cell structure having an inverted structure and including a double junction;

FIG. 4 is a schematic illustration showing controlled spalling of an inverted III-V solar cell structure from a germanium substrate;

FIG. 5 is a schematic illustration of a post-spalling process;

FIG. 6 is a table showing the flow of TmBi during growth of an InGaP emitter layer during three test runs;

FIG. 7 is a chart showing photoluminescence for an InGaP emitter subjected to various flow rates of TmBi;

FIG. 8 is a table showing band gap energy, open circuit voltage and short circuit current for solar cells having emitters subjected to the test runs of FIG. 6, and

FIG. 9 is a schematic illustration of a conventional solar cell structure having a single junction and wherein certain layers are grown in reverse order;

### DETAILED DESCRIPTION

Exemplary solar cell structures disclosed herein include stacked layers in reverse order. The exemplary structures may be flexible through the use of a back-reflector (e.g. SiO₂ or Al₂O₃) that allows use of a relatively thin absorber layer. A disordered InGaP emitter forming a heterostructure with a (In)GaAs base improves open circuit voltage, thereby increasing the conversion efficiency of the solar cell. Controlled spalling may be employed as part of the fabrication process for the exemplary solar cell structures disclosed herein.

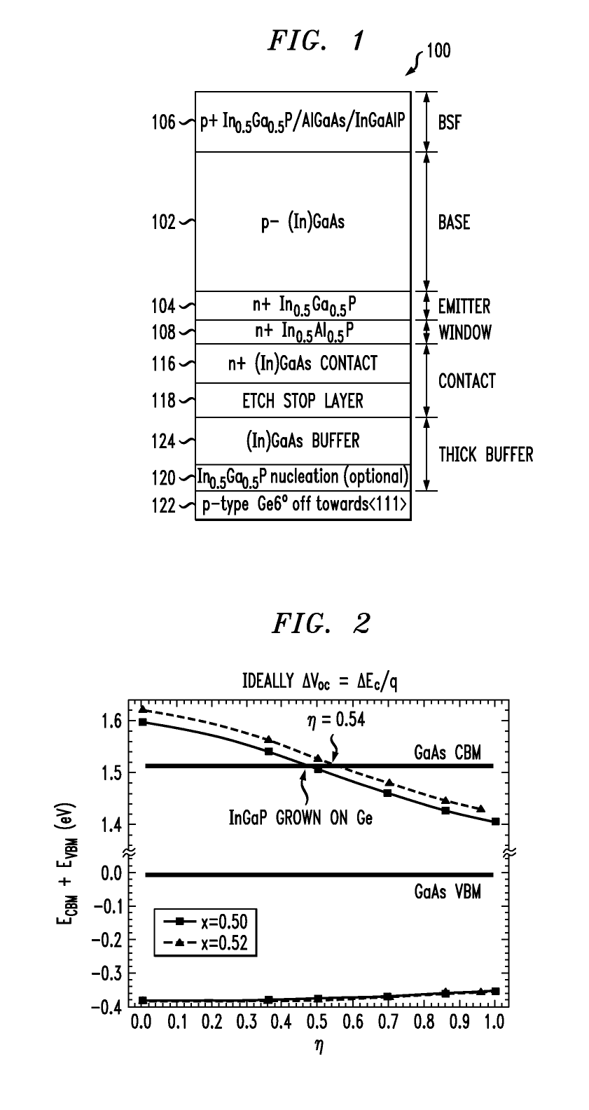

FIG. 1 shows a flexible solar cell structure 100 that can be produced by reverse order epitaxial growth followed by controlled spalling techniques such as disclosed in US Pub. Nos. 2010/0307572 and 2011/0048517, both of which are incorporated by reference herein. The structure 100 includes a light absorbing base layer 102 comprising p-(In)GaAs. In one exemplary embodiment, the base layer comprises Zn:In_{0.01}Ga_{0.99}As and is 3 μm in thickness with a dopant level of 1E17. The indium content of the base layer is 0-3%. The emitter layer 104 and the BSF layer 106 are formed below and above the base layer, respectively. As described further below, isoelectric surfactants may be used during formation of the emitter layer so that the emitter layer will be disordered, thereby increasing the bandgap. In this exemplary embodiment, the emitter layer is a n+In_{0.5}Ga_{0.5}P layer. A NID:InGaAs layer (not shown) may optionally be provided between the base layer 102 and emitter layer 104. The BSF layer may be comprised of materials such as InGaP, AlGaAs, or InGaAlP, or a combination of thereof. In one exemplary embodiment, the BSF layer has a thickness of 100 nm and is formed from Zn:In_{0.5}Ga_{0.5}P A contact layer (not shown) may be formed on the BSF layer, for example a 500 Å layer of Zn:In_{0.01}Ga_{0.99}As having a doping level of 2E18. A window layer 108 adjoins the emitter layer. Suitable materials for the window layer 108 include InAlP, and InGaAlP (e.g. In_{0.5}(Ga₁₋ₓAlₓ)_{0.5}P. In the latter example, aluminum is provided in a 20-50% ratio with respect to gallium. The window layer in the disclosed structure 100 is formed of n+InAlP, with compositions that make it lattice-matched or pseudomorphic to the Ge substrate. The active layers of the solar cell structure, namely the base 102, emitter layer 104, BSF layer 106 and window layer 108 are characterized by low defect density. A buffer layer 124 is formed on the substrate 122 and is comprised of an (In)GaAs layer in an exemplary embodiment. The buffer layer 124 can be grown directly on the germanium substrate 122. The indium concentration in the buffer layer is low and should not exceed 2-3%. The buffer region may further comprise an optional phosphide-based nucleation layer 120 (Si:In_{0.5}Ga_{0.5}P in this exemplary embodiment) between the germanium substrate 122 and the buffer layer 124. Silicon doping in the InGaP nucleation layer and in the InGaAs buffer layer is optional as these layers are not part of the active device structure. Such an optional layer 120 is generally grown in upright triple junction solar cells to prevent As diffusion in germanium, as As diffuses faster than phosphorus. This is to obtain shallower p/n junctions in germanium for such triple-junction cells. For the inverted structure where germanium is only used as a handle substrate, the growth of this layer is not required. The substrate 122 employed in this exemplary embodiment is p-type germanium 6° off towards <111>. In alternative embodiments, the germanium substrate could be p-type or n-type and 0-15° off from <111> or <110>. The higher degree of substrate misorientation towards <111> will result in a higher degree of disorder in the group-III sublattice, which in turn tends to increase the energy bandgap of InGaP. The increase in energy bandgap will lead to large energy band offset in conduction and valence bands. Using InGaP as the emitter material to form a heterostructure with the InGaAs base will improve the open circuit voltage of the solar cell structure, thereby increasing the conversion efficiency thereof. An etch stop layer 118 is formed between an ohmic contact layer 116 and the buffer layer 124. The etch stop layer may be comprised of InGaP, InAlP or AlGaAs. The contact layer 116 in an exemplary embodiment is comprised of n+(In)GaAs, the indium content not exceeding 2-3%. The structure 100 is relatively thin and flexible and can be part of a multi junction solar cell.

FIG. 2 shows the bandgap between the conduction band minimum (CBM) and valence band maximum (VBM) of GaAs. The value “x” in the graph denotes the gallium content in In₁₋ₓGaₓP. The figure provides a theoretical plot that is independent of the substrate material. The arrows indicate the typical extent of disorder for an In₁₋ₓGaₓP grown on (100) germanium. The largest portion of the band discontinuity in the InGaP/GaAs heterostructure is at the valence band. To increase ΔE_{c}, disordered InGaP is grown as discussed below thereby increasing V_{oc} and the resulting cell efficiency.

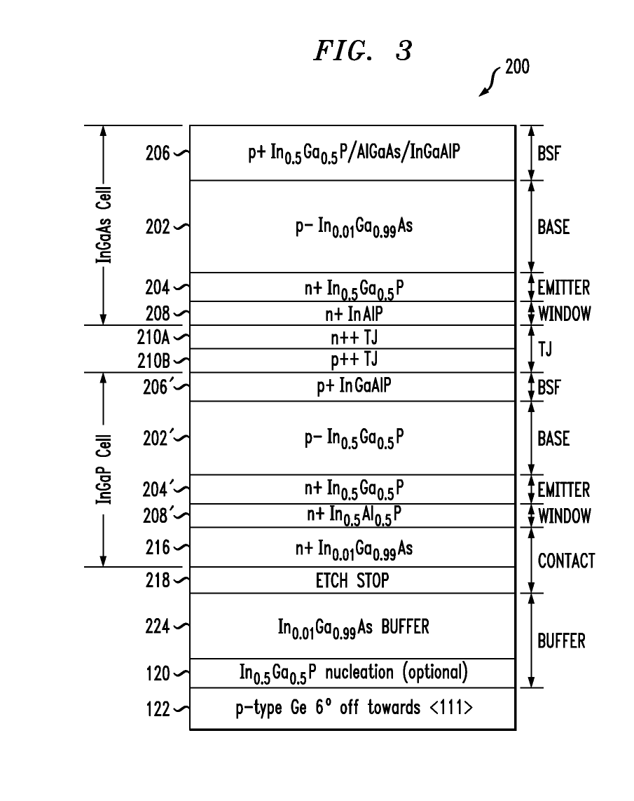

An inverted, flexible, double junction solar cell structure 200 comprising a disordered InGaP/GaAs heterostructure is shown in FIG. 3. This exemplary structure is grown on a substrate 122 comprising p-type germanium 6° off towards <111>. (As the germanium is used as a handle layer in inverted structures, it can be either n-type or p-type.) A first base layer 202 comprised of p−In_{0.01}Ga_{0.99}As adjoins a disordered emitter layer 204 comprising n+In_{0.5}Ga_{0.5}P and a BSF layer 206 comprised of p+In_{0.5}Ga_{0.5}P, AlGaAs, or InGaAlP or a combination of thereof, the BSF layer being formed above the base layer. A n+InAlP window layer 208 adjoins the emitter layer. A second cell includes a base layer 202′, emitter layer 204′ and BSF layer 206′. The base layer 202′ is comprised of p−In_{0.5}Ga_{0.5}P, the emitter layer n+In_{0.5}Ga_{0.5}P, and the BSF layer p+In_{0.5}Ga_{0.5}P, InGaAlP, InAlP. A highly doped tunnel junction comprised of n++ and p++ layers 210A, 210B is formed between the cells. An n+In_{0.5}Al_{0.5}P window layer 208′ adjoins the emitter layer 204′. A contact layer 216 adjoins the window layer 208′. In this exemplary embodiment, the contact layer comprises n+In_{0.01}Ga_{0.99}As. Etch stop and buffer layers 218, 224 are formed between the substrate 122 and the contact layer 216. The buffer layer 224 in this exemplary embodiment comprises In_{0.01}Ga_{0.99}As. An optional nucleation layer 120 may be provided between the substrate layer 122 and the buffer layer. Epitaxial methods known to those of skill in the art, including chemical vapor deposition such as MOCVD, can be employed for forming the layers of the structures 100, 200 disclosed herein on the germanium substrates 122.

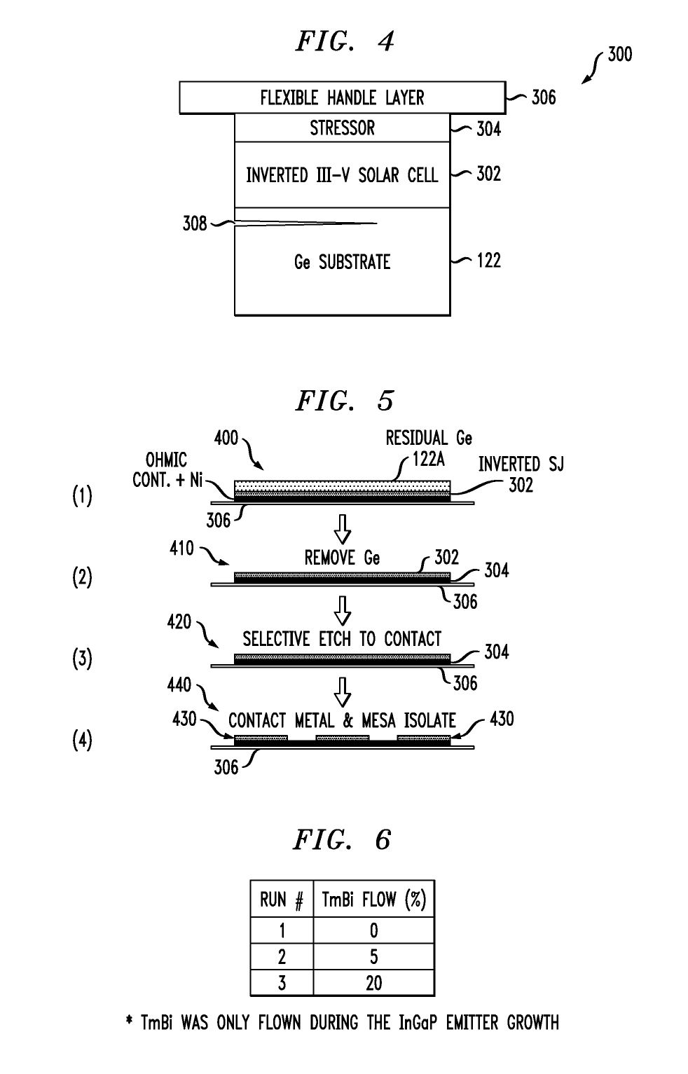

FIG. 4 schematically illustrates a solar cell structure 300 that facilitates the fabrication of a flexible solar cell structure. This structure 300 is fabricated by growing or depositing a tensile stressor layer 304 on an inverted III-V solar cell structure 302, such as the solar cell structures 100, 200 described above. A flexible handle layer 306 is then bonded to the stressor layer. If a back reflector is employed, it is formed between the solar cell structure 100 and the stressor layer. In this exemplary embodiment, the stressor layer is a metal such as nickel, tungsten or titanium while the flexible handle layer is a polyimide layer such as Kapton tape. The characteristics of the stressor layer, such as thickness and stress, and the flexible handle are adjusted to create a fracture 308 in the germanium substrate 122 on which the stacked, inverted layers of the structure 302 is formed. Controlled spalling is performed using the flexible handle layer 306 attached (e.g. bonded) to the stressor layer 304. Following the spalling process, the resulting structure 400 includes a layer 122A of residual germanium, the inverted solar cell structure, the stressor layer and the flexible handle, as shown in FIG. 5. (It should be noted that while reference number 302 continues to designate the solar cell structure comprising part of the structure 400 shown in FIG. 5, it has been flipped such that the emitter layer (e.g. layer 104) is now near the top of the cell and the structure 302 is no longer “inverted”.)

Referring further to FIG. 5, the residual germanium layer 122A is removed from the structure 400 obtained by spalling. This can be accomplished by chemical or physical etching. This step results in a structure 410 including a single junction stack in one exemplary embodiment comprising, for example, the layers shown in FIG. 1, the metal layer 304, and the flexible handle layer 306. The structure 100 may further include an ohmic contact layer (not shown) comprising (In)GaAs, in which case the structure 410 would further include such a layer adjoining the metal layer 304. Further selective etching removes the layers between the residual germanium layer 122A and the contact layer 116 to form a structure 420. The fourth illustrated step involves conventional front contact device fabrication. Contact metal is formed on the ohmic contact layer 116. A mesa isolation process creates individual solar cell structures 430 from the processed structure 100, which may be wafer size. The resulting structure 440 can be diced and further processed as deemed necessary or appropriate. It will be appreciated that the steps shown in FIG. 5 and discussed above can be applied to the inverted double junction solar cell structure 200 shown in FIG. 2.

As discussed above, the emitter layer 104 of the solar cell structure is formed by growing disordered InGaP. The emitter layer 204 adjoining the GaAs base layer 202 in the solar cell structure 200 shown in FIG. 3 is likewise formed by growing disordered InGaP. FIG. 6 is a table showing flow rates of two runs wherein a bismuth surfactant, namely trimethyl bismuth, was flown during emitter growth and a control (Run 1) where no surfactant was flown. The TmBi was only flown during InGaP emitter growth. Other surfactants, such as antimony (Sb) and tellurium (Te) can alternatively be used to grow disordered InGaP.

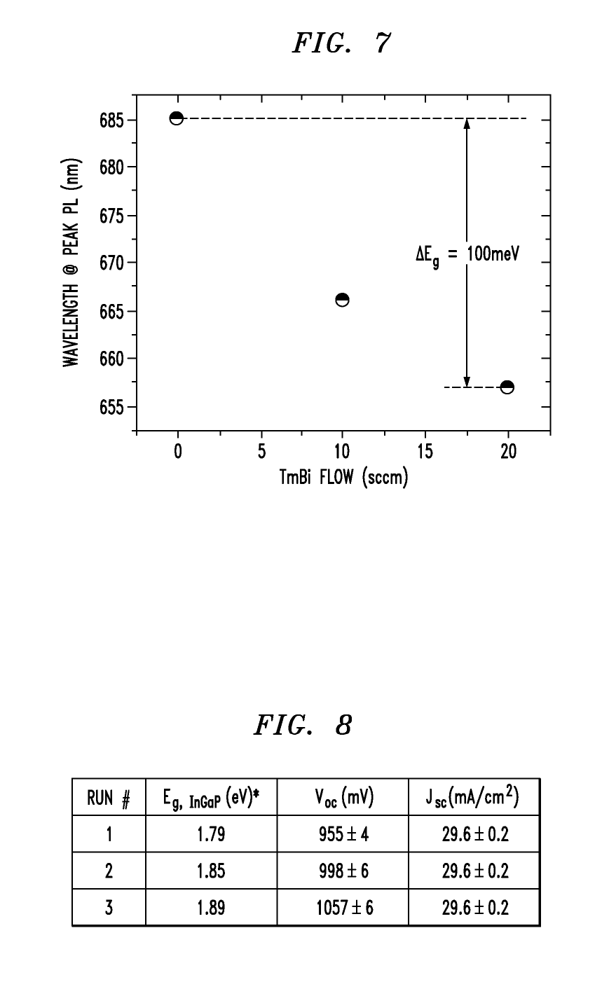

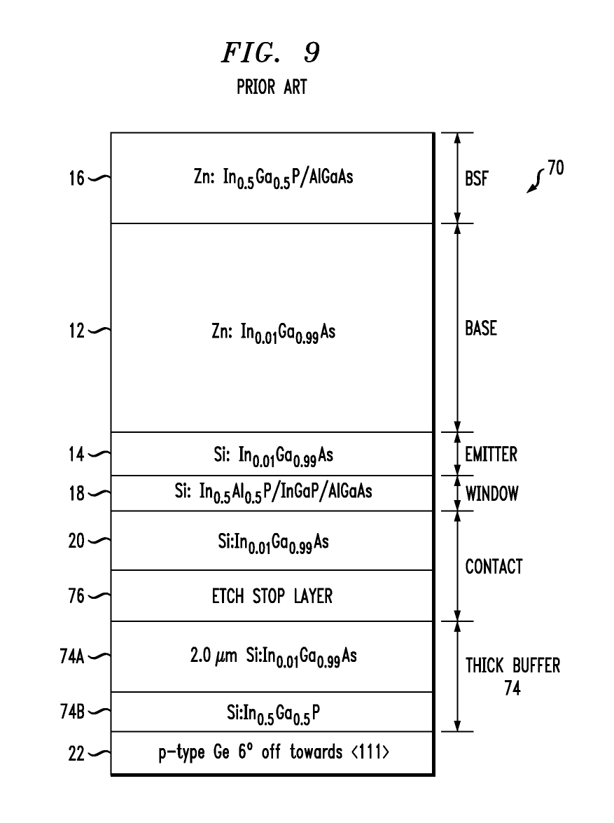

Most of the bandgap offset ΔE_{g} is attributable to changes in the conduction band as opposed to the valence band. By increasing disorder, the open circuit voltage V_{oc} is also increased. As shown in FIG. 7, ΔE_{g} is about 100 meV where the TmBi flow rate is twenty standard cubic centimeters per minute (20 sccm). While further disorder is possible at the forty percent TmBi flow rate, the surface characteristics of the resulting emitter layer are preferable at the lower twenty percent flow rate.

FIG. 8 is a table showing the effect of a bismuth surfactant on solar cell device performance for the trial runs shown in FIG. 6. The open circuit voltage increases with increasing surfactant while short circuit current J_{sc} remains the same. Emitter bandgap increases to 1.89 eV in Run #3.

Given the discussion thus far and with reference to the exemplary embodiments discussed above and the drawings, it will be appreciated that, in general terms, an exemplary method includes the steps of obtaining an inverted solar cell structure including a germanium substrate 122, a base layer 102 (202) comprising gallium arsenide, a back surface field layer 106 (206) adjoining the base layer, a disordered emitter layer 104 (204) between the substrate and the base layer and forming a heterostructure with the base layer, a window layer 108 (208) adjoining the emitter layer, and a contact layer 116 (216). The method further includes forming a stressor layer 304 on the inverted solar cell structure, attaching a flexible handle layer 306 to the stressor layer, and spalling through the germanium substrate 122, forming a solar cell structure (e.g. structure 400 as shown in FIG. 5) including the inverted solar cell structure 302, the stressor layer, the flexible handle layer, and a residual germanium layer 122A. In one or more embodiments, the method further includes the step of removing the residual germanium layer following spalling, thereby exposing the contact layer. A buffer layer 124 (224) between the contact layer and the residual germanium layer may further be removed. Contact metal is formed on the contact layer in some embodiments of the method. Mesa isolation, such as illustrated schematically in FIG. 5, may further be performed in one or more embodiments.

A second exemplary method includes providing a germanium substrate 122 and growing a single or multi junction solar cell structure 100, 200 including at least one gallium arsenide absorbing layer, e.g. layer 102 or layer 202, in inverted order on the germanium substrate, the step of growing the solar cell structure further including growing an emitter layer in the presence of an isoelectric surfactant to cause disordered growth of the emitter layer. The method further includes attaching a stressor layer 304 to the solar cell structure, attaching a flexible handle layer 306 to the stressor layer, spalling through the germanium substrate, and removing a residual germanium layer 122A from the solar cell structure.

In accordance with a further aspect, a photovoltaic structure is provided that comprises an inverted solar cell structure 302 comprising a germanium substrate 122, a base layer comprising gallium arsenide, a back surface field layer adjoining the base layer, a disordered emitter layer between the substrate and the base layer and forming a heterostructure with the base layer, a window layer adjoining the emitter layer, and a contact layer. A stressor layer 304 is attached to the inverted solar cell structure. A flexible handle layer 306 is attached to the stressor layer, the stressor layer and flexible handle layer being operable to cause a fracture 308 within the germanium substrate. The emitter layer comprises disordered indium gallium phosphide in one or more embodiments of the photovoltaic structure. The base layer comprises In_{0.01}Ga_{0.99}As in one or more embodiments thereof. The substrate may be p-type germanium 6° off towards <111> orientation in some embodiments. The photovoltaic structure further includes a buffer layer between the germanium substrate and the contact layer in one or more embodiments. The solar cell structure further includes a second heterostructure in some embodiments, such as the embodiment shown in FIG. 3.

A second exemplary structure includes a solar cell structure comprising a base layer comprising gallium arsenide, a back surface field layer adjoining the base layer, a disordered emitter layer between the substrate and the base layer and forming a first heterostructure with the base layer, a window layer adjoining the emitter layer, and a contact layer. A stressor layer 304 is attached to the solar cell structure 302 and a flexible handle layer 306 is attached to the stressor layer. The photovoltaic structure further comprises a buffer layer on the contact layer in one or more embodiments. The emitter layer comprises disordered indium gallium phosphide in one or more embodiments. The photovoltaic structure has a base layer comprising In_{0.01}Ga_{0.99}As in one or more embodiments. The solar cell structure further includes a second heterostructure in some embodiments. The second heterostructure comprises an indium gallium phosphide absorbing layer 202′ in some embodiments, as exemplified by the solar cell structure 200 shown in FIG. 3. The second heterostructure comprises an indium gallium phosphide emitter layer in some embodiments of the photovoltaic structure. The photovoltaic structure further includes a tunnel junction layer 210A, 210B between the first and second heterostructures in some embodiments. A second solar cell structure is provided in some embodiments, the stressor layer being attached to the second solar cell structure. FIG. 5 schematically illustrates multiple solar cell structures 430, each being attached to a stressor layer 304. The solar cell structures 430 have the same layers, but can differ in surface area. Metal contact layers are provided on the solar cell structure(s) in one or more embodiments.

Those skilled in the art will appreciate that the exemplary structures discussed above can be distributed in raw form or incorporated as parts of intermediate products or end products that benefit from having photovoltaic elements therein.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Terms such as “above” and “below” are used to indicate relative positioning of elements or structures to each other as opposed to relative elevation.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

1. A method comprising:
obtaining an inverted solar cell structure including:
a misoriented germanium substrate,
a base layer comprising gallium arsenide,
a back surface field layer adjoining the base layer,
a surfactant-induced disordered InGaP emitter layer between the germanium substrate and the base layer and forming a heterostructure with the base layer;
a window layer adjoining the emitter layer, and
a contact layer,
forming a stressor layer on the inverted solar cell structure;
attaching a flexible handle layer to the stressor layer, and
spalling through the germanium substrate to form, a solar cell structure that includes the inverted solar cell structure, the stressor layer, the flexible handle layer, and a residual germanium layer.

2. The method of claim 1, further comprising the step of removing the residual germanium layer following spalling, thereby exposing the contact layer.

3. The method of claim 2, further comprising forming contact metal on the contact layer.

4. The method of claim 2, further comprising performing mesa isolation with respect to the solar cell structure.

5. The method of claim 2, wherein the base layer comprises In_{0.01}Ga_{0.99}As.

6. The method of claim 2, wherein the germanium substrate is p-type germanium 6° off towards <111> orientation.

7. (canceled)

8. The method of claim 1, wherein the bandgap of the emitter layer is at least 1.85 eV.

9. A method comprising:
providing a germanium substrate;
growing a single or multi junction solar cell structure including at least one gallium arsenide absorbing layer in inverted order on the germanium substrate, the step of growing the solar cell structure further including growing an emitter layer in the presence of an isoelectric surfactant to cause disordered growth of the emitter layer;
attaching a stressor layer to the solar cell structure;
attaching a flexible handle layer to the stressor layer;
spalling through the germanium substrate, and
removing a residual germanium layer from the solar cell structure.

10. The method of claim 9, wherein the emitter layer comprises indium gallium phosphide.

11. The method of claim 10, wherein the isoelectric surfactant comprises bismuth.

12. The method of claim 10, wherein the absorbing layer comprises In_{0.01}Ga_{0.99}As.

13. The method of claim 10, wherein the substrate is p-type or n-type germanium 6° off towards <111> orientation.

14. The method of claim 13, wherein the solar cell structure includes a contact layer, further comprising forming contact metal on the contact layer.

15. The method of claim 10, further including forming a back reflector between the solar cell structure and the stressor.

16. The method of claim 10, wherein the stressor layer comprises a metal.
